(19) United States
(12) Patent Application Publication
(10) Pub. No.: US 2026/0076200 A1
(43) Pub. Date: Mar. 12, 2026

(54) ELECTRONIC DEVICE

(71) Applicant: Advanced Semiconductor Engineering, Inc., Kaohsiung (TW)

(72) Inventors: Chang-Yu LIN, Kaohsiung (TW); Pei-Jung YANG, Kaohsiung (TW); Chi-Han CHEN, Kaohsiung (TW)

(73) Assignee: Advanced Semiconductor Engineering, Inc., Kaohsiung (TW)

(21) Appl. No.: 18/827,665

(22) Filed: Sep. 6, 2024

(51) Int. Cl. H01L 23/00; G02B 6/42; G02B 6/43; H01L 25/16

(52) U.S. Cl. CPC H10W 42/121; G02B 6/4274; G02B 6/43; G02B 6/4269; H10W 74/15; H10W 90/00; H10W 90/722; H10W 90/732

(57) ABSTRACT

An electronic device is provided. The electronic device includes a photonic component, a connector, and a first reinforcement element. The photonic component is configured to optically couple to an optical element. The connector is disposed under the photonic component and configured to support the optical element. The first reinforcement element is disposed over the photonic component and configured to allow the photonic component to withstand a force generated by disposing the connector under the photonic component.

### BACKGROUND

### 1. Technical Field

The present disclosure relates generally to an electronic device.

### 2. Description of the Related Art

Currently, a fiber array unit (FAU) may be disposed adjacent to an edge of a photonic IC (PIC) in an electronic device for optical transmission through edge coupling, and a connector may be used to connect the FAU to optically couple to the edge of the PIC. With the applications of such electronic device increase and the size of the electronic device decreases, there is an increasing need to improve the optical alignment and the reliability of the electronic device including the FAU and the PIC.

### SUMMARY

In one or more arrangements, an electronic device includes a photonic component, a connector, and a first reinforcement element. The photonic component is configured to optically couple to an optical element. The connector is disposed under the photonic component and configured to support the optical element. The first reinforcement element is disposed over the photonic component and configured to allow the photonic component to withstand a force generated by disposing the connector under the photonic component.

In one or more arrangements, an electronic device includes a photonic component and a warpage control element. The photonic component includes an optical channel configured to optically couple to an optical element. The warpage control element is connected to the photonic component and is configured to reduce an alignment shift between the optical channel and the optical element.

In one or more arrangements, an electronic device includes a substrate, a photonic component, a connector, and a first reinforcement element. The photonic component is positioned over the substrate and includes a portion that is at least partially free from vertically overlapping the substrate. The connector is attached to the portion of the photonic component. The first reinforcement element is disposed over the photonic component and is configured to reduce deformation of the portion of the photonic component.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of an electronic device in accordance with some arrangements of the present disclosure.

FIG. 1B is a top view of an electronic device in accordance with some arrangements of the present disclosure.

FIG. 1C is a bottom view of an electronic device in accordance with some arrangements of the present disclosure.

FIG. 1D is a cross-section of an electronic device in accordance with some arrangements of the present disclosure.

FIG. 1E is a cross-section of an electronic device in accordance with some arrangements of the present disclosure.

FIG. 2A is a cross-section of an electronic device in accordance with some arrangements of the present disclosure.

FIG. 2B is a cross-section of an electronic device in accordance with some arrangements of the present disclosure.

FIG. 3A is a top view of an electronic device in accordance with some arrangements of the present disclosure.

FIG. 3B is a cross-section of an electronic device in accordance with some arrangements of the present disclosure.

FIG. 4 shows simulation results of warpage of an electronic device in accordance with some arrangements of the present disclosure.

FIG. 5A, FIG. 5B, FIG. 5C, and FIG. 5D illustrate various stages of an exemplary method for manufacturing an electronic device in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

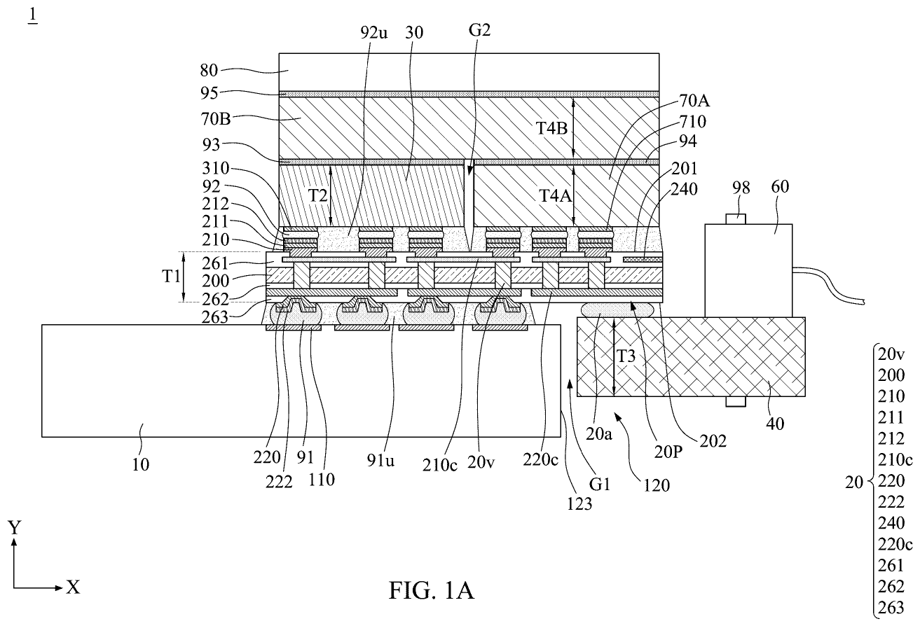

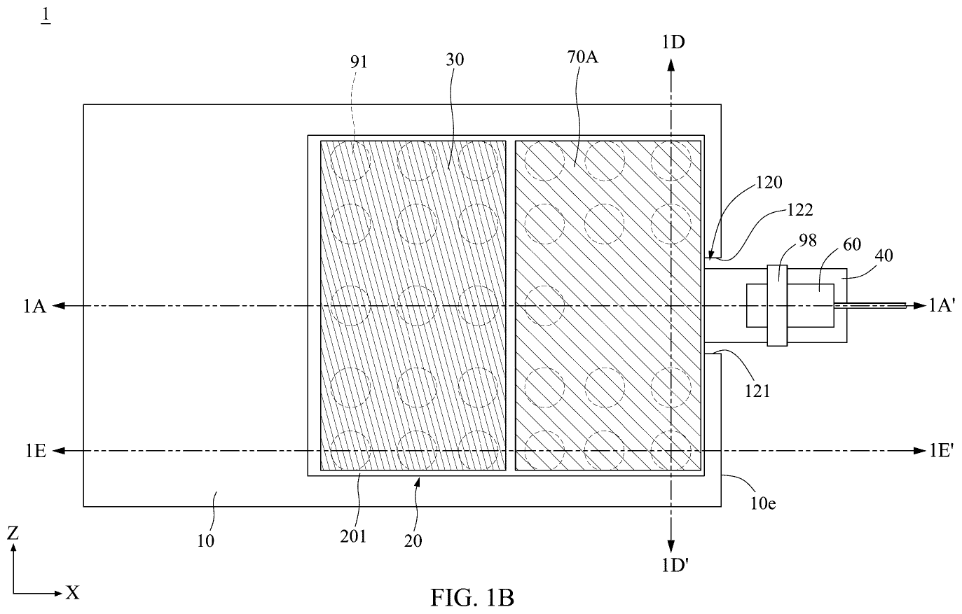

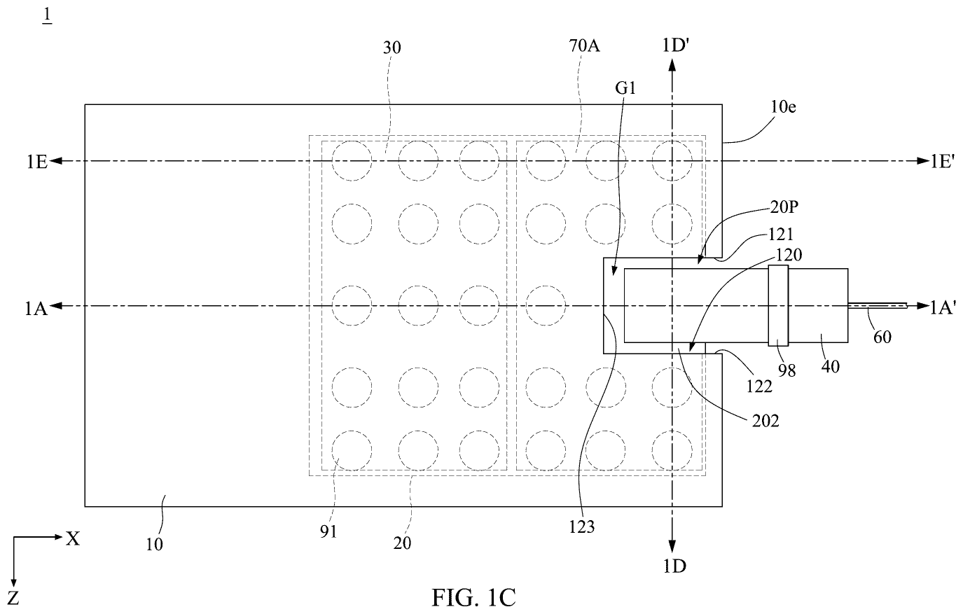

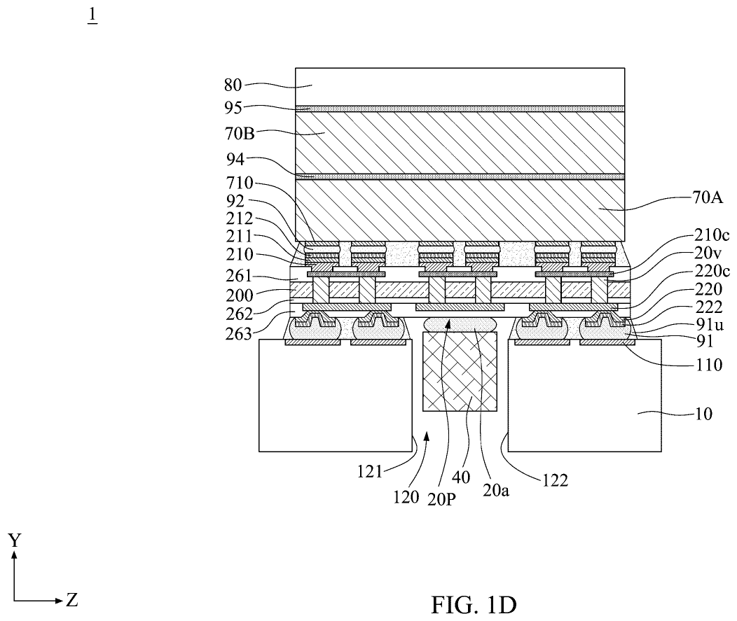

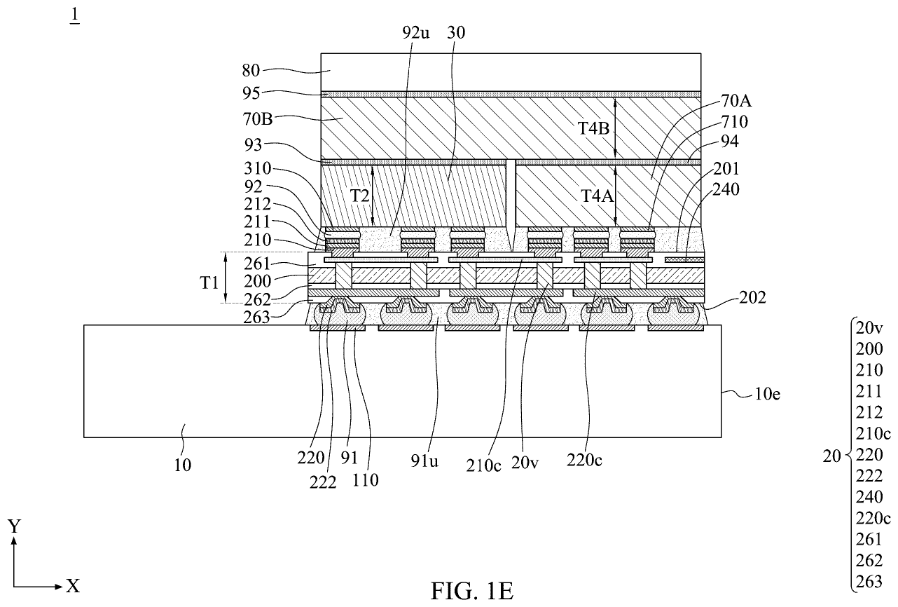

FIG. 1A is a cross-section of an electronic device 1 in accordance with some arrangements of the present disclosure. FIG. 1B is a top view of an electronic device 1 in accordance with some arrangements of the present disclosure. FIG. 1C is a bottom view of an electronic device 1 in accordance with some arrangements of the present disclosure. FIG. 1D is a cross-section of an electronic device 1 in accordance with some arrangements of the present disclosure. FIG. 1E is a cross-section of an electronic device 1 in accordance with some arrangements of the present disclosure. In some arrangements, FIG. 1A is a cross-section along a line 1A-1A′ in FIG. 1B and FIG. 1C. In some arrangements, FIG. 1D is a cross-section along a line 1D-1D′ in FIG. 1B and FIG. 1C. In some arrangements, FIG. 1E is a cross-section along a line 1E-1E′ in FIG. 1B and FIG. 1C.

The electronic device 1 may include a substrate 10, a photonic component 20, an electronic component 30, a connector 40, an optical element 60, reinforcement elements 70A and 70B, a heat sink 80, and electrical contacts 91. In some arrangements, the electronic device 1 may be or include an optoelectronic package.

The substrate 10 may support the photonic component 20. The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and a plurality of conductive vias. In some embodiments, the substrate 10 includes a ceramic substrate, a metal plate, an organic substrate, or a leadframe. In some embodiments, the substrate 10 may include a two-layer substrate which includes a core layer and a conductive material and/or structure disposed on an upper surface and a bottom surface of the substrate 10. The conductive material and/or structure may include a plurality of conductive traces. In some arrangements, the substrate 10 includes conductive pads 110. In some arrangements, referring to FIG. 1C, the substrate 10 defines a recess 120 (also referred to as “an opening”). The recess 120 may be recessed from an edge 10e of the substrate 10. In some arrangements, referring to FIGS. 1A, 1C, and 1D, a sidewall (e.g., surfaces 121, 122, and 123) of the substrate 10 defines the recess 120 (or the opening).

The photonic component 20 may be disposed over and electrically connected to the substrate 10. The photonic component 20 may have a surface 202 facing the substrate 10 and a surface 201 opposite to the surface 202. The surface 201 may be an active surface. The surface 202 may be a backside surface or a passive surface. In some arrangements, the photonic component 20 is configured to optically couple to an optical element 60. In some arrangements, the photonic component 20 is configured to optically couple to an optical element 60 by edge coupling. The photonic component 20 may include a portion 20P that is at least partially free from vertically overlapping the substrate 10. The photonic component 20 (or the portion 20P) may overhang the substrate 10 in a cross-sectional view perspective. The photonic component 20 may be or include a photonic integrated circuit (PIC), a laser diode, a receiver, a waveguide, a photodetector, a photodiode, a semiconductor optical amplifier (SOA), a grating coupler, a fiber coupling structure, an optical modulator (e.g., Mach-Zehnder modulator or microring modulator), or a combination thereof.

In some arrangements, the photonic component 20 includes a substrate layer 200, conductive pads 210 and 220, barrier layers 212 and 222, conductive layers 210c, 220c, and 211, conductive vias 20v, an optical channel 240, and dielectric layers 261, 262, and 263. The substrate layer 200 may be or include a semiconductor layer, e.g., a silicon layer. The conductive layers 211 may be formed on the conductive pads 210, the barrier layers 212 may be formed on the conductive layers 211, and the barrier layers 222 may be formed on the conductive pads 220. The conductive layer 210c may be or include a circuit layer. The circuit layer may include one or more circuits configured to provide a photoelectric conversion. The conductive vias 20v may electrically connect the conductive layer 210c to the conductive layer 220c. The conductive layer 220c may be electrically connected to the conductive pads 220. The optical channel 240 may be configured to optically couple to the optical element 60. The optical channel 240 may be or include an optical waveguide. The conductive pads 210 and 220, the conductive layers 210c, 220c, and 211, and the conductive vias 20v may include one or more conductive materials such as a metal or metal alloy. Examples include gold (Au), silver (Ag), aluminum (Al), copper (Cu), or an alloy thereof. The barrier layers 212 and 222 may include nickel (Ni). The photonic component 20 may have a thickness T1 equal to or less than about 100 μm, 80 μm, 60 μm, or 50 μm. The thickness T1 may be about 50 μm to about 100 μm.

The electronic component 30 may be disposed over the electrically connected to the photonic component 20. In some arrangements, the electronic component is electrically connected to the substrate 10 through conductive vias 20v in the photonic component 20. In some arrangements, the electronic component 30 includes conductive pads 310. In some arrangements, the electronic component 30 is electrically connected to the photonic component 20 through the conductive pad 310s, connection elements 92, the barrier layers 212, the conductive layers 211, and the conductive pads 210. The connection elements 92 may include conductive bumps. The connection elements 92 may be encapsulated by a protective element 92u. The protective element 92u may include an underfill. In some embodiments, the underfill includes an epoxy resin, a molding compound (e.g., an epoxy molding compound or other molding compound), polyimide, a phenolic compound or material, a material including a silicone dispersed therein, or a combination thereof. In some arrangements, the electronic component 30 is free from vertically overlapping a gap G1 between the substrate 10 and the connector 40. The electronic component 30 may be or include an electronic integrated circuit (EIC). In some arrangements, the electronic component 30 includes a modulator driver (DRV), a trans-impedance amplifier (TIA), or a combination thereof. The electronic component 30 may have a thickness T2 equal to or greater than the thickness T1 of the photonic component 20.

The connector 40 may be disposed under the photonic component 20. In some arrangements, the connector 40 is attached to the surface 202 of the photonic component 20. In some arrangements, the connector 40 is attached to the portion 20P of the photonic component 20. In some arrangements, connector 40 is attached to the photonic component 20 through an adhesive 20a. In some arrangements, the adhesive 20a may have a thickness of less than about 5 μm, 4 μm, or 3 μm. In some arrangements, the connector 40 is configured to support the optical element 60. In some arrangements, the connector 40 vertically overlaps the optical channel 240. In some arrangements, the thickness T1 of the photonic component 20 is less than a thickness T3 of the connector 40. In some arrangements, the connector 40 is disposed in a space (e.g., the recess 120) defined by the substrate 10 and the photonic component 20. In some arrangements, a portion of the connector 40 is protruded beyond the recess 120. In some arrangements, the recess 120 of the substrate 10 is configured for accommodating at least a portion of the connector 40. In some arrangements, the recess 120 is recessed from the edge 10e of the substrate 10 and configured to accommodate a portion of the connector 40. In some arrangements, the sidewall (or the surfaces 121, 122, and 123) of the substrate 10 is spaced apart from the connector 40. The connector 40 may include or be formed of transparent rigid structure, e.g., a quartz plate.

The optical element 60 may be disposed on and supported by the connector 40. In some arrangements, the optical element 60 is engaged with or connected to the connector 40. A fixing member 98 may further fix the optical element 60 to the connector 40. In some arrangements, the optical element 60 includes one or more optical fibers. In some arrangements, the optical element 60 is or includes an optical fiber array unit (FAU).

The reinforcement element 70A may be disposed over the photonic component 20. In some arrangements, the reinforcement element 70A is configured to allow the photonic component 20 to withstand a force generated by disposing the connector 40 under the photonic component 20. In some arrangements, the reinforcement element 70A is configured to reduce a deformation of the portion 20P of the photonic component 20. The reinforcement element 70A may be referred to as a warpage control element. In some arrangements, the reinforcement element 70A (or the warpage control element) is configured to reduce an alignment shift between the optical channel 240 and the optical element 60. In some arrangements, the reinforcement element 70A (or the warpage control element) includes a dummy die configured not to provide electrical connection.

In some arrangements, the reinforcement element 70A is connected to the photonic component 20. In some arrangements, the reinforcement element 70A is connected to the photonic component 20 through an electrically isolated connection element. The electrically isolated connection element may include a dummy connection element. In some arrangements, a pad 710 (also referred to as “a dummy conductive pad”, “a dummy conductive bump” or “an electrically isolated pad”) of the reinforcement element 70A is connected to the conductive pad 220 through a connection element 92. The connection element 92 that connects to the pad 710 may be a dummy connection element or an electrically isolated pad. In some arrangements, the connector 40 and the reinforcement element 70A (or the warpage control element) are connected to opposite surfaces 201 and 202 of the photonic component 20. In some arrangements, the reinforcement element 70A vertically overlaps the gap G1 between the substrate 10 and the connector 40.

In some arrangements, the reinforcement element 70A includes a discrete component. In some arrangements, the reinforcement element 70A is distinct from the photonic component 20. In some arrangements, the reinforcement element 70A is free of a logic circuit. In some arrangements, the reinforcement element 70A includes a dummy substrate (e.g., a dummy silicon substrate). In some arrangements, the reinforcement element 70A includes a dummy die. The reinforcement element 70A may have a thickness T4A equal to or greater than the thickness T1 of the photonic component 20. The thickness T4A of the reinforcement element 70A may be substantially the same as the thickness T2 of the electronic component 30.

The reinforcement element 70B may be disposed over the photonic component 20 and the reinforcement element 70A. In some arrangements, the reinforcement element 70B is disposed over the electronic component 30 and the reinforcement element 70A. In some arrangements, the reinforcement element 70B vertically overlaps a gap G2 between the electronic component 30 and the reinforcement element 70A. In some arrangements, the reinforcement element 70B is connected to the electronic component 30 through an adhesive layer 93. In some arrangements, the reinforcement element 70B is connected to the reinforcement element 70A through an adhesive layer 94. The adhesive layers 93 and 94 may be or include insulating adhesives. The adhesive layers 93 and 94 may be or include die attach films (DAFs). The adhesive layers 93 and 94 may include at least a thermal interface material (TIM).

In some arrangements, the reinforcement element 70B includes a discrete component. In some arrangements, the reinforcement element 70B is distinct from the photonic component 20, the electronic component 30, and the reinforcement element 70A. In some arrangements, the reinforcement element 70B is free of a logic circuit. In some arrangements, the reinforcement element 70B includes a dummy substrate (e.g., a dummy silicon substrate). In some arrangements, the reinforcement element 70B includes a dummy die. In some arrangements, the reinforcement element 70B includes a dummy die. The reinforcement element 70B may have a thickness T4B equal to or greater than the thickness T1 of the photonic component 20. The thickness T4B of the reinforcement element 70B may be substantially the same as the thickness T4A of the reinforcement element 70A.

The heat sink 80 may be disposed over the reinforcement element 70A. In some arrangements, the heat sink 80 is disposed over the reinforcement element 70B. In some arrangements, the heat sink 80 is connected to the reinforcement element 70B through an adhesive layer 95. The adhesive layer 95 may be or include an insulating adhesive. The adhesive layer 95 may be or include a die attach film (DAF). The adhesive layer 95 may include a thermal interface material (TIM). The heat sink 80 may be, for example, a pipe, a fin-type heat sink, a planar heat sink, a liquid cooling tube, or a thermal vapor compressor (TVC).

The electrical contacts 91 may be disposed between the substrate 10 and the photonic component 20. In some arrangements, the electrical contacts 91 are encapsulated by a protective element 91u. In some arrangements, the conductive pads 110 of the substrate 10 are electrically connected to the conductive pads 220 of the photonic component 20 through some of the electrical contacts 91 (also referred to as “a first portion of the electrical contacts 91”). In some arrangements, some of the electrical contacts 91 (also referred to as “a second portion of the electrical contacts 91”) are disposed under the reinforcement element 70A. Referring to FIG. 1D, a portion of the connector 40 is between at least two of the electrical contacts 91 (or the second portion of the electrical contacts 91). The electrical contacts 91 (or the second portion of the electrical contacts 91) that support the reinforcement element 70A may be dummy bumps configured not to provide electrical connection. The electrical contacts 91 (or the second portion of the electrical contacts 91) that support the reinforcement element 70A may electrically connect the substrate 10 to the photonic component 20. The electrical contacts 91 may be or include solder balls. In some arrangements, the electrical contacts 91 include controlled collapse chip connection (C4) bumps, a ball grid array (BGA), or a land grid array (LGA). The protective element 91u may be or include an underfill.

In some other arrangements, FIG. 1A shows a cross-section along the line 1A-1A′ and the line 1E-1E′ in FIG. 1B and FIG. 1C, and FIG. 1D shows a cross-section along the line 1D-1D′ in FIG. 1B and FIG. 1C. The substrate 10 may have an edge (e.g., the surface 123 shown in FIG. 1A) spaced apart from the connector 40. The reinforcement element 70A may overhang the substrate 10. The portion 20P of the photonic component 20 may protrude beyond the surface 123 and overhang the substrate 10. The reinforcement element 70A may vertically overlap the gap G1 between the substrate 10 and the connector 40.

When the connector 40 is used to fix the optical element 60 (e.g., the FAU) to an edge portion (e.g., the portion 20P) of the photonic component 20, the difficulty of assembling can be reduced. In addition, the photonic component 20 requires to be relatively thin to allow the formation of the conductive vias 20v within the photonic component 20, so as to allow the photonic component 20 to serve as an interposer that connects the electronic component 30 to the substrate 10. However, the relatively thin photonic component 20 may suffer from warpage due to its relatively low structural strength. The optical channel 240 (or the waveguide) of the photonic component 20 may warp or bend along with the warpage of the photonic component 20, and thus optical alignment shift between the optical channel 240 and the optical element 60 may occur. Moreover, the photonic component 20 may be further deformed seriously and thereby damaged or cracked due to its relatively low structural strength.

According to some arrangements of the present disclosure, with the design of the reinforcement element 70A, the deformation of the photonic component 20 can be reduced significantly. Therefore, the warpage can be reduced, the optical alignment can be improved, and the reliability of the electronic device 1 can be increased.

In addition, according to some arrangements of the present disclosure, the reinforcement element 70A is disposed on the portion 20P of the photonic component 20 that is not supported by the substrate 10. Therefore, the structural strength of a portion of the photonic component 20 can be uniformly increased by being supported by the electrical contacts 91 over the substrate 10, and the structural strength of another portion (the portion 20P) of the photonic component 20 that is not supported by the electrical contacts 91 can be increased by being connected to the reinforcement element 70A. Therefore, the structural strength of the entire photonic component is substantially uniformly increased without any weak point, such that the photonic component 20 can be prevented from being damaged by the force generated by attaching the connector 40 to the photonic component 20.

Moreover, according to some arrangements of the present disclosure, the substrate 10 includes a recess 120 for accommodating a portion of the connector 40, and the remaining portion of the substrate 10 are disposed with the electrical contacts 91 (or dummy bumps) to support the photonic component 20. Therefore, the area of the photonic component 20 supported by the electrical contacts 91 can be increased, thus the structural strength of the photonic component 20 as well as the reliability of the electronic device 1 are increased.

Furthermore, according to some arrangements of the present disclosure, the reinforcement element 70B is disposed over and connected to both of the electronic component 30 and the reinforcement element 70A. The reinforcement element 70B covers a range greater than that of the reinforcement element 70A and connects to not only the reinforcement element 70A but also the electronic component 30. Therefore, the reinforcement element 70B can further increase the structural enhancement provided by the reinforcement element 70A, and the reinforcement element 70B can also improve the structural strength of the electronic component 30 and the integrity of the entire electronic device 1, thereby increasing the reliability of the electronic device 1.

In addition, according to some arrangements of the present disclosure, with the design of the relatively thin adhesive 20a that connects the connector 40 to the photonic component 20, the thickness variation of the relatively thin adhesive 20a is relatively small accordingly. As such, the small thickness variation provides a relatively small variation in the distance between the connector 40 and the photonic component 20. Therefore, the optical alignment shift between the optical channel 240 and the optical element 60 can be reduced accordingly, which is advantageous to improving the optical coupling efficiency.

Moreover, according to some arrangements of the present disclosure, the connector 40 including a quartz plate allows UV light to pass through to cure polymeric materials (e.g., the protective element 91u that encapsulates the electrical contacts 91). In addition, the connector 40 made of quartz can further withstand a relatively high temperature. Therefore, the processing window is increased, process is simplified, and the flexibility of the process is increased.

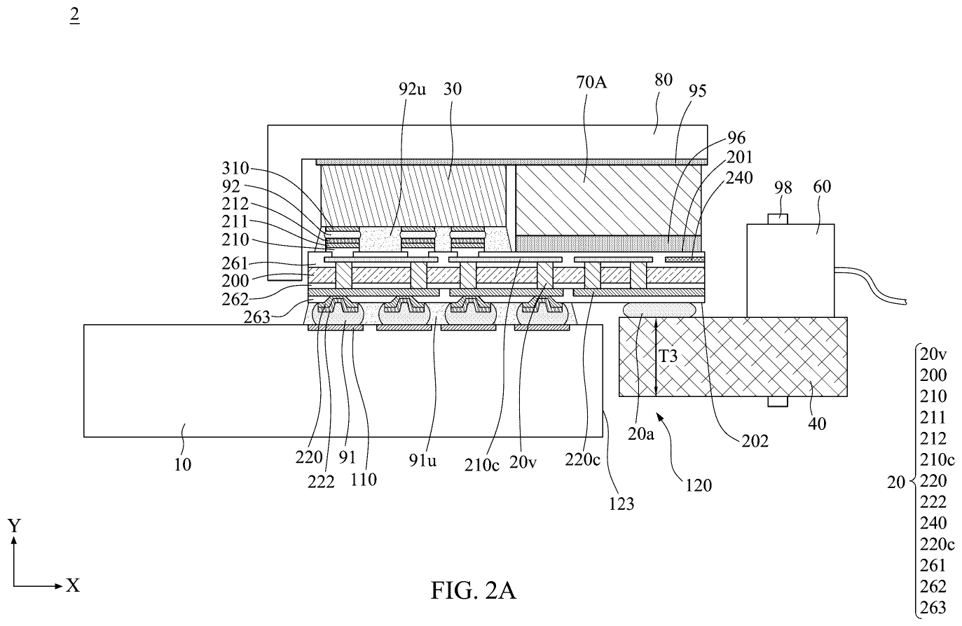

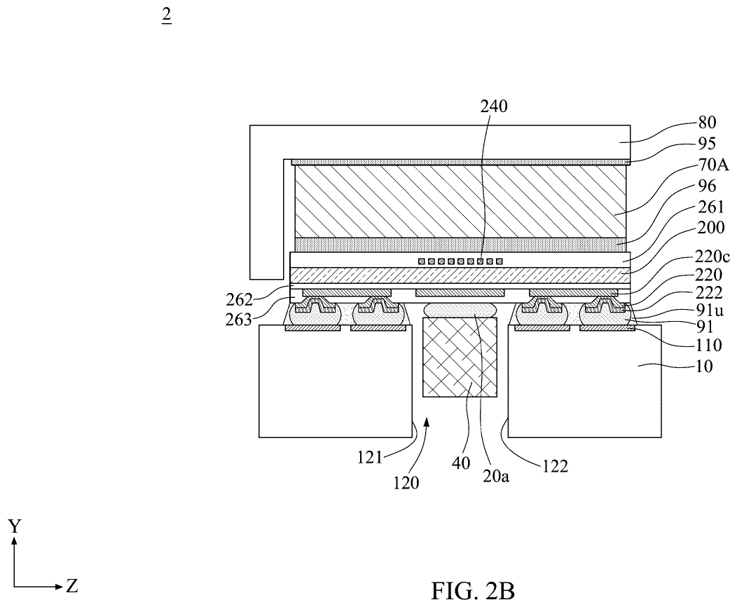

FIG. 2A is a cross-section of an electronic device 2 in accordance with some arrangements of the present disclosure. FIG. 2B is a cross-section of an electronic device 2 in accordance with some arrangements of the present disclosure. In some arrangements, FIG. 2A is a cross-section along x-axis of the electronic device 2, and FIG. 2B is a cross-section along y-axis of the electronic device 2. The electronic device 2 is similar to the electronic device 1, and the differences therebetween are described as follows.

In some arrangements, the heat sink 80 is connected to the electronic component 30 and the reinforcement element 70A through the adhesive layer 95 (or the TIM). In some arrangements, the reinforcement element 70A is connected to the photonic component 20 through an electrically isolated connection element. The electrically isolated connection element may include a dummy connection element. In some arrangements, a bottom surface of the reinforcement element 70A is connected to the dielectric layer 261 of the photonic component 20 through a connection element 96. The connection element 96 that connects to the reinforcement element 70A may be an adhesive layer (e.g., DAF).

According to some arrangements of the present disclosure, the adhesive layer is used to connect the reinforcement element 70A to the photonic component 20. The thickness of the adhesive layer can be adjusted with a relatively high flexibility. Therefore, the top surface of the reinforcement element 70A can be substantially aligned with the top surface of the electronic component 30 by adjusting the thickness of the adhesive layer when the electronic component 30 and the reinforcement element 70A have different thicknesses. Therefore, the heat sink 80 can be attached to a relatively planar surface, and thus the bonding strength between the heat sink 80 and the electronic component 30 and the reinforcement element 70A can be improved.

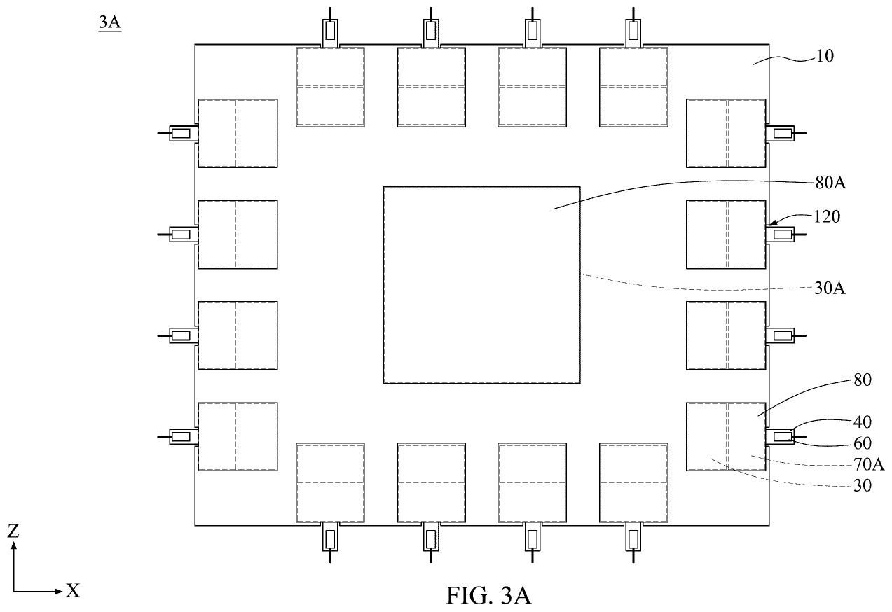

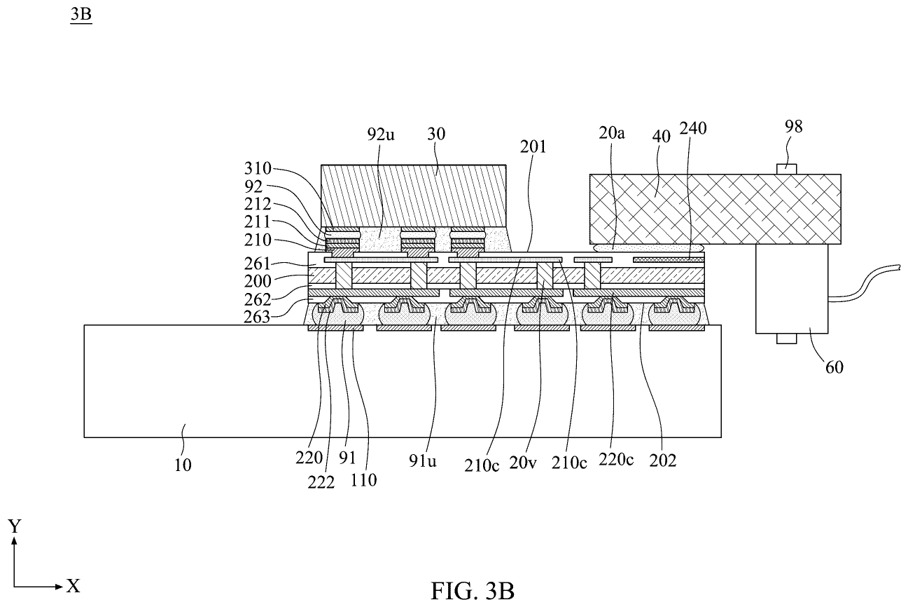

FIG. 3A is a top view of an electronic device 3A in accordance with some arrangements of the present disclosure. The electronic device 3A is similar to the electronic device 1, and the differences therebetween are described as follows.

In some arrangements, the electronic device 3A includes a substrate 10, photonic components 20, electronic components 30 and 30A, connectors 40, an optical element 60, reinforcement elements 70A, and heat sinks 80 and 80A. In some arrangements, the substrate 10 defines a plurality of recesses 120 around a periphery of the substrate 10. The electronic device 3A may include a plurality of the structures illustrated in FIGS. 1A-1E with the substrate 10 shared by the plurality of structures. In some arrangements, reinforcement elements 70B may be further disposed between the heat sinks 80 and the reinforcement elements 70A.

The electronic component 30A may be disposed over the substrate 10 and adjacent to the photonic components 20. In some arrangements, the electronic component 30A is surrounded by the photonic components 20. In some arrangements, the electronic component 30A is configured to communicate with electronic devices or electronic components outside of the electronic device 3A through the photonic components 20 by optical communication. In some arrangements, the photonic component 20 may receive an electrical signal from the electronic component 30A, e.g., by an interconnection structure within the substrate 10, and convert the electrical signal to an optical signal which is then optically coupled to the optical element 60 and then transmitted to the electronic devices or electronic components outside of the electronic device 3A. The electronic component 30A may include a processing component. In some arrangements, the electronic component 30A may include an ASIC, an FPGA, a GPU, or the like, or a combination thereof.

In some arrangements, the heat sink 80A is disposed over and connected to the electronic component 30A. The heat sink 80A may be, for example, a pipe, a fin-type heat sink, a planar heat sink, a liquid cooling tube, or a TVC.

FIG. 3B is a cross-section of an electronic device 3B in accordance with some arrangements of the present disclosure. The electronic device 3B is similar to the electronic device 1, and the differences therebetween are described as follows.

In some arrangements, the connector 40 and the electronic component 30 are disposed at the same side of the photonic component 20. In some arrangements, the photonic component 20 is supported by the substrate 10 and the electrical contacts 91 so as to have a sufficient strength to withstand a force generated by disposing the connector 40 on the photonic component 20. In some arrangements, the substrate 10 and the electrical contacts 91 support the photonic component 20 and are configured to reduce an alignment shift between the optical channel 240 and the optical element 60. In some arrangements, the connector 40 and the electronic component 30 are disposed on the photonic component 20 after the photonic component 20 is attached to the substrate 10.

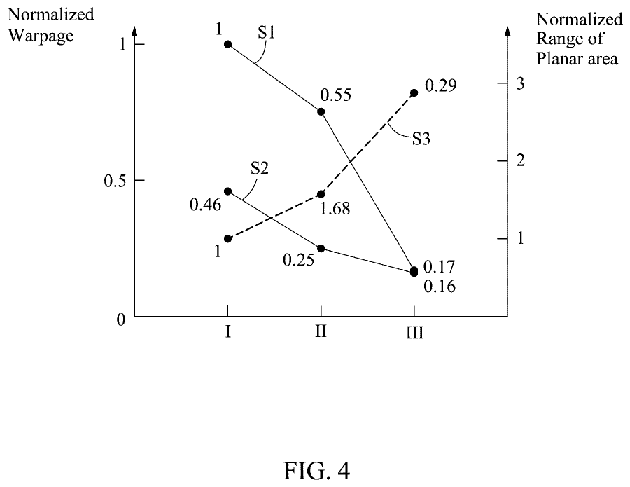

FIG. 4 shows simulation results of warpage of an electronic device in accordance with some arrangements of the present disclosure. Curve S1 shows simulation results of normalized warpage of the portion 20P of the photonic component 20 of the electronic devices at room temperature according to embodiments I, II, and III. Curve S2 shows simulation results of normalized warpage of the portion 20P of the photonic component 20 of the electronic devices at an elevation temperature (260° C.) according to embodiments I, II, and III. Curve S3 shows simulation results of normalized ranges of the planar areas of the portion 20P of the photonic component 20 of the electronic devices according to embodiments I, II, and III. The term “planar area” indicates an area with warpage of less than about 1 μm adjacent to where an edge coupling is occurred. Embodiment I refers to an electronic device with the portion 20P of the photonic component 20 that overhangs the substrate 10. Embodiment II refers to an electronic device having one reinforcement element, for example, including a structure similar to that shown in FIG. 2A and FIG. 2B. Embodiment III refers to an electronic device having two reinforcement elements, for example, including a structure similar to that shown in FIG. 1A to FIG. 1E.

As shown in FIG. 4, curves S1 and S2 show that with the arrangements of the reinforcement elements, the warpage of the portion 20P, which is adjacent to where edge coupling between the photonic component 20 and the optical element 60 occurs, is reduced, and thus optical alignment can be increased. In addition, the warpage can be further reduced by arranging more reinforcement elements.

As shown in FIG. 4, curve S3 shows that with the arrangements of the reinforcement elements, the low-warpage area adjacent to where edge coupling between the photonic component 20 and the optical element 60 occurs increases, and thus optical alignment can be increased. In addition, the low-warpage area can be further enlarged by arranging more reinforcement elements.

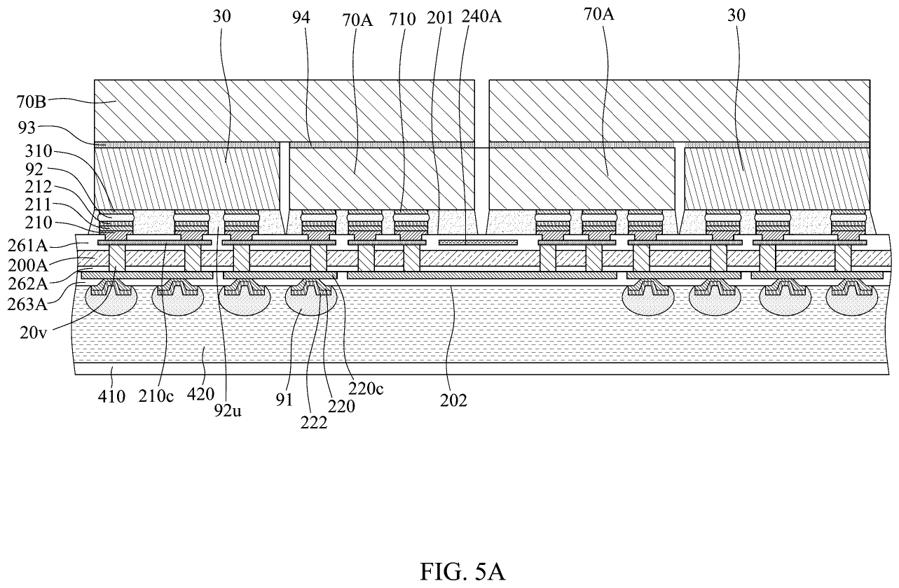

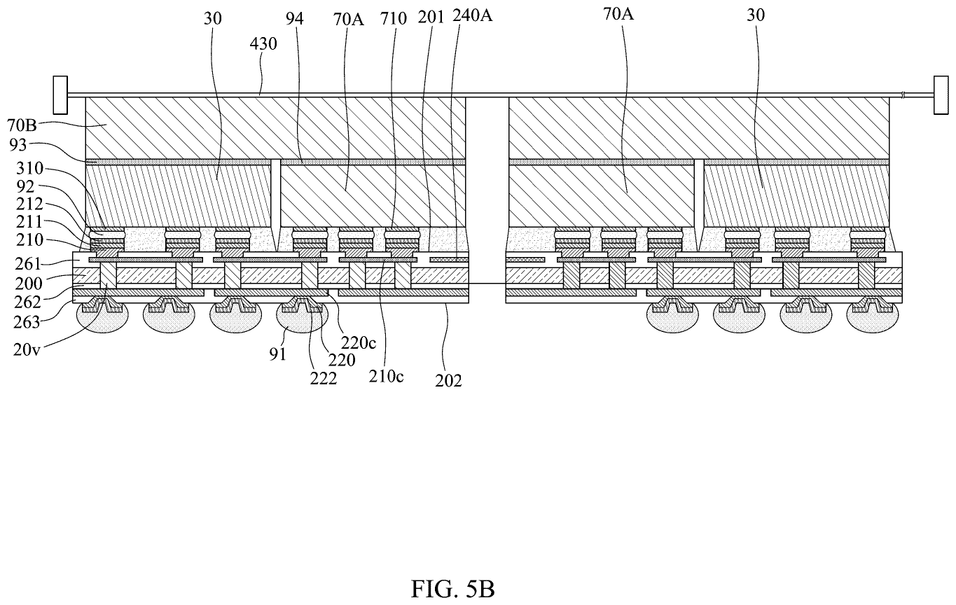

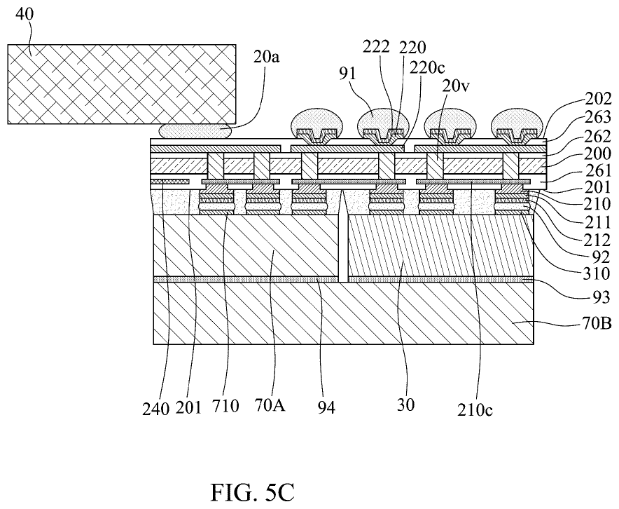

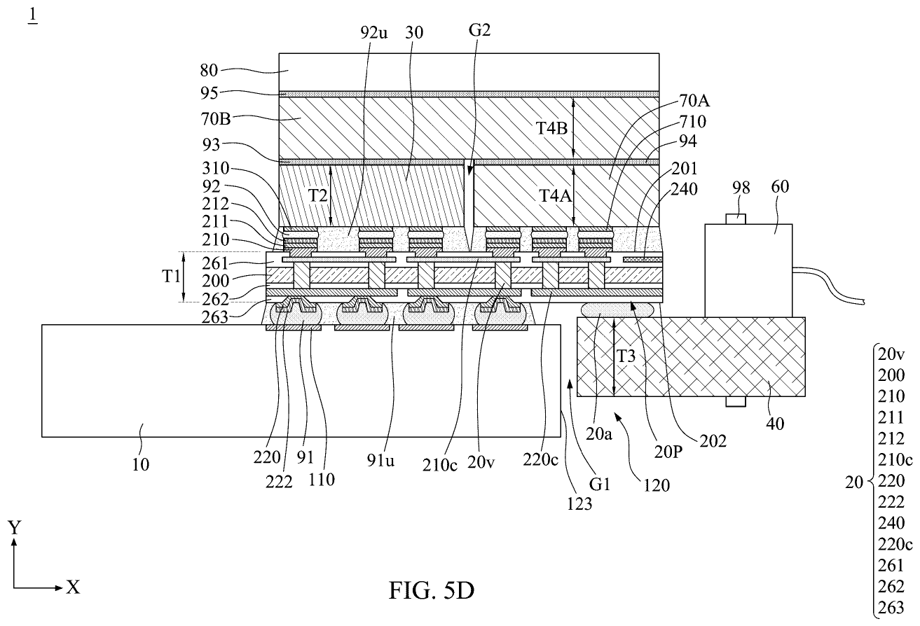

FIG. 5A, FIG. 5B, FIG. 5C, and FIG. 5D illustrate various stages of an exemplary method for manufacturing an electronic device 1 in accordance with some embodiments of the present disclosure.

Referring to FIG. 5A, a wafer level photonic component including a substrate layer 200A, conductive pads 210 and 220, barrier layers 212 and 222, conductive layers 210c, 220c, and 211, conductive vias 20v, an optical channel 240A, and dielectric layers 261A, 262A, and 263A may be provided, and electrical contacts 91 may be disposed on the conductive pads 220. The above wafer level structure may be disposed over a carrier 410 with the electrical contacts 91 embedded in the gel layer 420 on the carrier 410. The carrier 410 may be a rigid carrier and configured to support the wafer level photonic component, and the gel layer 420 is configured to provide stress buffer and accommodating spaces for the electrical contacts 91. In some arrangements, a plurality of electronic components 30 and a plurality of reinforcement elements 70A are disposed over and connected to the wafer level photonic component. In some arrangements, a plurality of reinforcement elements 70B are further disposed over and connected to the electronic components 30 and the reinforcement elements 70A. According to some arrangements of the present disclosure, the carrier 410 can support the wafer level photonic component and prevent it from being cracked from relatively weak regions when bonding the connectors 40 to the wafer level photonic component.

Referring to FIG. 5B, the structure illustrate in FIG. 5A may be disposed over a tape 430, and a singulation operation may be performed to form a plurality of photonic components 20. The gel layer 420 and the carrier 410 may be removed.

Referring to FIG. 5C, a connector 40 may be bonded to an edge portion of the photonic component 20 by an adhesive 20a. In some arrangements, each of the singulation structures illustrated in FIG. 5B may be disposed over and supported by a carrier or a tray, and then the photonic component 20 of each of the singulation structures is bonded with a connector 40. In some arrangements, the connector 40 may over hang the photonic component 20. The reinforcement element 70A provides a supporting force to increase the structural strength of the photonic component 20 so as to reduce warpage of the photonic component 20.

Referring to FIG. 5D, the photonic component 20 may be connected to a substrate 10 through the electrical contacts 91, and an optical element 60 (or an optical fiber) may be engaged with or connected to the connector 40 so as to fix the optical element 60 to the connector 40. In some arrangements, after the photonic component 20 is connected to the substrate 10, the optical element 60 is fixed to the connector 40. In some arrangements, a heat sink 80 is further disposed over and connected to the reinforcement element 70B. As such, the electronic device 1 may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a photonic component configured to optically couple to an optical element;
a connector disposed under the photonic component and configured to support the optical element; and
a first reinforcement element disposed over the photonic component and configured to allow the photonic component to withstand a force generated by disposing the connector under the photonic component.

2. The electronic device as claimed in claim 1, wherein the first reinforcement element comprises a discrete component.

3. The electronic device as claimed in claim 2, wherein the first reinforcement element is free of a logic circuit.

4. The electronic device as claimed in claim 3, wherein the first reinforcement element comprises a dummy silicon substrate.

5. The electronic device as claimed in claim 1, further comprising:
a substrate supporting the photonic component; and
an electronic component disposed over the photonic component and electrically connected to the substrate through conductive vias in the photonic component.

6. The electronic device as claimed in claim 5, wherein the first reinforcement element overhangs the substrate.

7. The electronic device as claimed in claim 5, wherein the connector is disposed in a space defined by the substrate and the photonic component.

8. The electronic device as claimed in claim 1, further comprising a substrate supporting the photonic component, wherein the substrate defines a recess for accommodating the connector.

9. The electronic device as claimed in claim 8, wherein a portion of the connector is protruded beyond the recess.

10. The electronic device as claimed in claim 1, further comprising a second reinforcement element disposed over the photonic component and the first reinforcement element.

11. The electronic device as claimed in claim 1, further comprising a heat dissipation element disposed over the first reinforcement element.

12. An electronic device, comprising:
a photonic component comprising an optical channel configured to optically couple to an optical element; and
a warpage control element connected to the photonic component and configured to reduce an alignment shift between the optical channel and the optical element.

13. The electronic device as claimed in claim 12, further comprising a connector attached to the photonic component and configured to support the optical element, wherein the optical channel vertically overlaps the connector.

14. The electronic device as claimed in claim 13, wherein the connector and the warpage control element are connected to opposite surfaces of the photonic component.

15. The electronic device as claimed in claim 13, further comprising:
a substrate supporting the photonic component and defining an opening configured to accommodate a portion of the connector; and
a plurality of electrical contacts between the photonic component and the substrate, wherein the portion of the connector is between at least two of the electrical contacts.

16. The electronic device as claimed in claim 12, wherein the warpage control element is connected to the photonic component through an electrically isolated connection element.

17. An electronic device, comprising:
a substrate;
a photonic component over the substrate and comprising a portion at least partially free from vertically overlapping the substrate;
a connector attached to the portion of the photonic component; and
a first reinforcement element disposed over the photonic component and configured to reduce a deformation of the portion of the photonic component.

18. The electronic device as claimed in claim 17, wherein the portion of the photonic component overhangs the substrate.

19. The electronic device as claimed in claim 17, wherein the first reinforcement element vertically overlaps a gap between the substrate and the connector.

20. The electronic device as claimed in claim 19, further comprising an electronic component disposed over the photonic component and free from vertically overlapping the gap.
